(19) United States
(12) Patent Application Publication
(10) Pub. No.: US 2026/0123164 A1
(43) Pub. Date: Apr. 30, 2026

(54) VERTICAL STACKED MICRODISPLAY PANEL

(71) Applicant: WAVELORD CO., LTD, Hwaseong-si (KR)

(72) Inventors: Juneo SONG, Suwon-si (KR); Ji Hyung MOON, Gunpo-si (KR); Hyeong Seon YUN, Paju-si (KR); Tae Kyoung KIM, Osan-si (KR)

(73) Assignee: WAVELORD CO., LTD, Hwaseong-si (KR)

(21) Appl. No.: 19/097,931

(22) Filed: Apr. 2, 2025

(30) Foreign Application Priority Data
Oct. 30, 2024 (KR) 10-2024-0151592
Jan. 21, 2025 (KR) 10-2025-0008958

(51) Int. Cl. H10H 29/80; H10H 29/34; H10H 29/45

(52) U.S. Cl. CPC H10H 29/962; H10H 29/34; H10H 29/45; H10H 29/8321

(57) ABSTRACT

The present invention relates to a vertically stacked microdisplay panel, which includes a back wafer having an upper surface on which a plurality of complementary metal-oxide-semiconductor (CMOS) electrode pads are arranged, a plurality of light-emitting diode (LED) stacks, each of which includes a plurality of light-emitting units and a plurality of bonding layers that are stacked in a vertical direction and is arranged on one of a plurality of CMOS electrode pads, and a common electrode formed on the plurality of LED stacks, wherein each of the plurality of LED stacks, by forming a short path in at least one of the plurality of light-emitting units, allows a current to flow through the light-emitting unit in which the short path is not formed, and emits only a specific color, and the short path has a preset depth and a preset width.

According to the present invention, since a color filter is unnecessary despite the adoption of a vertically stacked tandem structure, the color quality of a microdisplay can be significantly improved, and process complexity and productivity can be significantly improved.

### CROSS-REFERENCE TO RELATED APPLICATION

This application claims priority to and the benefit of Korean Patent Application No. 2024-0151592 filed on Oct. 30, 2024, and Korean Patent Application No. 2025-0008958 filed on Jan. 21, 2025, the disclosure of which is incorporated herein by reference in its entirety.

### BACKGROUND

### 1. Field of the Invention

The present invention relates to a vertically stacked microdisplay panel, and more specifically, to a vertically stacked light-emitting diode on silicon (LEDoS) microdisplay panel that utilizes an engineering monolithic epitaxy wafer method so that no alignment process between light-emitting diode (LED) stacks and complementary metal-oxide-semiconductor (CMOS) electrode pads is required and that allows each LED stack to emit only a specific color so that no color filter is required.

### 2. Discussion of Related Art

The types of implementation of the Metaverse which has recently been focused on are classified into four types: virtual reality (VR), augmented reality (AR), mixed reality (MR), and extended reality (XR). Among these types, a Metaverse ecosystem centered on XR, which is a reality that links VR, AR, and MR, is expected to develop in the future. In order to effectively implement the Metaverse ecosystem centered on XR, software for a next-generation computing platform that can provide an innovative user experience, as well as devices (smart glasses, head-mounted displays, etc.) that include a microdisplay with a diagonal length of less than 1 inch as a core component, are required. In particular, the development of high-performance microdisplay panel technology is absolutely necessary to provide the greatest sense of immersion, visibility, and convenience to XR users and minimize dizziness.

As illustrated in FIG. 1, a conventional microdisplay panel 10 uses a technology in which a Si complementary metal-oxide-semiconductor (CMOS) semiconductor wafer process and a high-resolution, high-brightness, ultra-small display process are combined, and the conventional microdisplay panel 10 may have a structure in which a Si CMOS wafer 11 having a (100) crystal plane of 4″ or larger and equipped with a plurality of CMOS electrode pads 12 and a transparent wafer 13 of 4″ or larger and equipped with a micro light-emitting diode (microLED) electrode pad 14 and a plurality of microLED chips 15 are bonded through conductive bonds 16. Meanwhile, the types of microdisplay panels expected to be applied to XR devices include liquid crystal (LC)-based LC on Si (LCoS), organic light-emitting diode (OLED)-based OLED on Si (OLEDoS), ultra-small microLED-based LED on Si (LEDoS) with a pixel size of less than 5 μm, etc. For VR with low pixel density displays, LCOS and OLEDoS are mainly being developed and mass-produced.

However, with the development of implementation technology for the metaverse, the need for lightweight AR, MR, and XR devices with high pixel density microdisplay panels is increasing, and the development of LEDoS technology, which is theoretically considered as an ideal solution based on the superior properties of inorganic materials, is urgently required to meet the need, but the microdisplay panel platform for the development of LEDoS technology has not yet been established.

Ultra-small microLED-based LEDoS with a pixel size of less than 5 μm has advantages of an excellent power-to-performance ratio and a short response speed when applied to XR devices, and the ultra-small microLED-based LEDoS is formed of inorganic materials, has a long lifetime, and has the advantage of efficient power use, reducing heat generation, and enabling long-term battery use. In particular, since XR devices have a very short distance between the display and the eyes, even a small delay in image conversion may easily cause discomfort such as dizziness or the like. Therefore, LEDoS, which has a nanosecond response speed, is considered to be the most suitable for XR devices compared to LCoS and OLEDoS, which have microsecond response speeds.

Furthermore, it is evaluated that the biggest reason why LEDoS is focused on in AR, MR, and XR devices rather than VR devices is due to its brightness and luminous efficiency. Since smart glasses may be worn in any location, high brightness is an essential condition for normal operation even in outdoor environments such as sunlight and the like. In theory, a microLED supports brightness of tens to millions of nits, and while an OLED is organic, a microLED is inorganic, and thus the microLED also has the advantage of high luminous efficiency.

However, despite the above-described advantages, the biggest reason why ultra-small microLED-based LEDoS with a pixel size of less than 5 μm has not established itself as a major component of XR devices is the difficulty of mass production. That is, LEDoS requires millions of ultra-small microLEDs that should be fixed on a Si CMOS wafer, the process difficulty is high and the yield is very low, which leads to an increase in manufacturing costs and forms high component prices, and this is reflected in the final consumer price leading to a high-priced XR device, which makes it difficult to meet market demand.

Meanwhile, as illustrated in FIG. 2, LEDoS to which group III-V compound (GaN, GaP, etc.) microLED light sources have been applied until recently has been developed through traditional approaches such as \textcircled{1} monolithic integration of wafers (or unit dies) composed of microLED arrays on Si CMOS wafers, or \textcircled{2} hybridization between wafers (or unit dies) on blue, green, and red light source wafers (or unit dies) on which Si CMOS wafers or microLED arrays are manufactured.

One of the biggest obstacles to the development of LEDoS to which blue, green, and red microLED light sources composed of group III-V compounds have been applied until recently is the difficulty in securing a solution for pixels with a size of less than 5 μm. Recently, pixels with a size on the level of 5 μm have been successfully demonstrated using monolithic integration technology, and some demonstration models developed based on hybridization technology have achieved pixels on the order of 10 μm by being manufactured using sapphire flip chips. In addition, it has been proven that it is possible to reduce pixels with a size on the level of 5 μm in the same way by using micro tube wiring in hybridization technology. However, both monolithic integration and hybridization technologies are impractical solutions with significant difficulties in mass production in terms of quality and yield and thus have a problem of making mass production difficult.

The monolithic integration and hybridization technologies described above have the common characteristic of separately designing and manufacturing a front plane wafer composed of a group III-V compound microLED array and a Si CMOS back plane wafer composed of numerous integrated circuit (IC) electrode pad arrays, and then assembling the front plane wafer and the Si CMOS back plane wafer. However, since the microLED arrays manufactured on the Si CMOS wafer at the unit die level or wafer level should be ultra-finely aligned in either method, there is a problem in that the alignment is limited by the precision of the process-related device, which in turn has a significant impact on pixels and limitations of distances (pitches) between the pixels, and mass production is also difficult. Accordingly, a new alternative solution is required to avoid the above-described constraints on ultra-fine alignment in order to manufacture LEDoS to which high-resolution, high-brightness, and high-speed operation of blue, green, and red microLED light sources with a pixel size of less than 5 μm and a pitch of smaller than 3 μm are applied.

Accordingly, although several impressive demonstrations with pixels of 6 μm have been recently released using engineering monolithic epitaxy wafers manufactured through a low-temperature metal bonding process between Si CMOS wafers and microLED array wafers, mass production is considered impossible due to low quality and yield issues caused by low-temperature metal bonding, and the use of small-diameter wafers of 6 inches or less. Above all, when ultra-fine pixels of less than 3 μm for microdisplays are manufactured using conventional engineering monolithic epitaxy wafers using metal bonding, the patterning etching process faces even greater difficulties.

As another example, recently, a novel engineered monolithic epitaxy wafer approach that has achieved great success in solving the problems limiting the brightness and resolution of LEDoS with group III-V compound microLED light sources, while providing a mass production and low-cost manufacturing solution using 12-inch large-diameter Si CMOS wafers has been proposed.

As illustrated in FIG. 3, specifically, a process of using the corresponding technology, that is, an engineering monolithic epitaxy wafer, is accomplished through the following four-step process. \textcircled{1} First, using an LED epitaxy wafer, an LED epitaxy cut to a predetermined size (e.g., 4 mm×6 mm) is aligned and bonded onto a 12-inch large-diameter Si blanket wafer at a unit die level. Thereafter, a growth wafer and buffer layer of the LED epitaxy are removed and then planarized, only an LED active layer of a predetermined thickness (e.g., approximately 1.5 μm) is left on the large-diameter Si blanket wafer, and then an LED fab process producing a pixel chip is completed. \textcircled{2} Next, the Si blanket wafer on which the pixel chip is completed is bonded to a 12-inch CMOS IC Si wafer at a wafer level through multilayer metal bonding. \textcircled{3} Next, the Si blanket wafer is removed. \textcircled{4} Next, a remaining process is finally performed on a microLED array that functions as a pixel on the CMOS IC Si wafer.

However, in step \textcircled{1}, when the LED epitaxy unit die is bonded onto the Si blanket wafer, there is a limitation that alignment should be performed on the CMOS IC Si wafer of the same size to bond them, and in step \textcircled{2}, when bonding with a multilayer metal including a low-melting-point metal (Sn, In), there is a problem in that the phenomenon of overflowing low-melting-point metal components relatively easily occurs, resulting in a short defect where the microLED sub-pixel arrays within the panel are electrically connected to each other or to the neighboring CMOS IC electrode pad array. Furthermore, in step \textcircled{2}, there is a problem in that defects occur due to the difficulty in ultra-fine alignment wafer bonding between the Si blanket wafer (i.e., front plane wafer) and the CMOS IC Si wafer due to the optically opaque nature of the Si blanket wafer and the multilayer metal bonding layer. Here, the ultra-fine alignment means aligning the microLED array, which is a plurality (hundreds to tens of millions) of ultra-small pixel chips mounted on a Si blanket wafer, and the CMOS IC electrode pad array mounted on the CMOS IC Si wafer on a 1:1 basis.

That is, the engineering monolithic epitaxy wafer approach presented in the above-described technologies is evaluated to provide a solution that brings us one step closer to the implementation of ultra-small microLED-based LEDoS with a pixel size of less than 5 μm. However, there are quality and yield issues caused by the use of a metal (low temperature, multilayer) in wafer bonding, and it is very difficult to manufacture high-resolution microdisplays with ultra-fine pixels of less than 3 μm. In addition, there are problems due to some alignment processes, and thus a new alternative is required.

Further, a vertically stacked tandem structure of the conventional microdisplay color filters is still used to implement full color, and thus there are disadvantages in terms of color quality, process complexity, and productivity.

### RELATED ART DOCUMENT

### Patent Document

(Patent Document 0001) Korean Laid-open Patent Publication No. 10-2018-0009116

### SUMMARY OF THE INVENTION

The present invention is directed to providing a vertically stacked LEDOS microdisplay panel that utilizes an engineering monolithic epitaxy wafer when bonding a front wafer and a back wafer so that an alignment process between light-emitting diode (LED) stacks and complementary metal-oxide-semiconductor (CMOS) electrode pads is not required and in which each LED stack emits only a specific color so that color filter is not required.

According to an aspect of the present invention, there is provided a vertically stacked microdisplay panel which includes a back wafer having an upper surface on which a plurality of CMOS electrode pads are arranged, a plurality of LED stacks, each of which includes a plurality of light-emitting units and a plurality of bonding layers that are stacked in a vertical direction and is arranged on one of a plurality of CMOS electrode pads, and a common electrode formed on the plurality of LED stacks, wherein each of the plurality of LED stacks, by forming a short path in at least one of the plurality of light-emitting units, allows a current to flow through the light-emitting unit in which the short path is not formed, and emits only a specific color, and the short path has a preset depth and a preset width.

Further, the plurality of LED stacks may include a first LED stack for emitting only a first color, a second LED stack for emitting only a second color, and a third LED stack for emitting only a third color, and the first LED stack, the second LED stack, and the third LED stack may be formed so that a first light-emitting unit is disposed on the CMOS electrode pad and emits the first color, a second light-emitting unit is disposed on the first light-emitting unit and emits the second color, and a third light-emitting unit is disposed on the second light-emitting unit and emits the third color.

Further, the first LED stack, by forming the short path in each of the third light-emitting unit and the second light-emitting unit, may allow a current to flow only through the first light-emitting unit and emit only the first color, the second LED stack, by forming the short path in each of the first light-emitting unit and the third light-emitting unit, may allow a current to flow only through the second light-emitting unit and emit only the second color, and the third LED stack, by forming the short path in each of the first light-emitting unit and the second light-emitting unit, may allow a current to flow only through the third light-emitting unit and emit only the third color.

Further, the light-emitting unit may include a first semiconductor region having a first conductivity, an active region, and a second semiconductor region having a second conductivity, a first ohmic contact electrode may be formed in contact with the first semiconductor region, and a second ohmic contact electrode may be formed in contact with the second semiconductor region.

Further, the width of the short path may be smaller than a width of the light-emitting unit.

Further, a protective layer may be formed on the first ohmic contact electrode, and the short path may be formed to pass through the protective layer and the first ohmic contact electrode.

Further, the width of the short path may correspond to the width of the light-emitting unit.

Further, the short path may be formed to extend from at least the first ohmic contact electrode to a portion of the second semiconductor region at a lower side.

Further, the short path may be formed to extend from at least the first ohmic contact electrode to the second semiconductor region at the lower side.

Further, the short path may be formed to extend from at least the first ohmic contact electrode to the second ohmic contact electrode at the lower side.

Further, the short path may be formed to extend from at least the first ohmic contact electrode to the bonding layer at the lower side.

Further, the short path may be formed to extend from at least the first ohmic contact electrode at an upper side to a portion of the first ohmic contact electrode at the lower side.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a diagram illustrating a structure of a microdisplay panel of the related art;

FIG. 2 is a diagram illustrating a light-emitting diode on silicon (LEDoS) development approach of the related art;

FIG. 3 is a diagram illustrating an approaching method using an engineering monolithic epitaxy wafer of the related art;

FIG. 4 is a diagram illustrating the entirety of a vertically stacked microdisplay panel according to a first embodiment of the present invention;

FIG. 5 is a diagram illustrating a plurality of light-emitting diode (LED) stacks of the vertically stacked microdisplay panel according to the first embodiment of the present invention that each emit only a specific color;

FIG. 6 illustrates diagrams of short paths of the vertically stacked microdisplay panel according to the first embodiment of the present invention that are formed to have different depths;

FIG. 7 is a diagram illustrating a transparent layer that is removed through a protective layer of the vertically stacked microdisplay panel according to the first embodiment of the present invention;

FIG. 8 is a diagram illustrating the entirety of a vertically stacked microdisplay panel according to a second embodiment of the present invention;

FIG. 9 illustrates diagrams of short paths of the vertically stacked microdisplay panel according to the second embodiment of the present invention that are formed to have different depths;

FIG. 10 is a flowchart of a method of manufacturing the vertically stacked microdisplay panel of the present invention;

FIGS. 11 and 12 illustrate a process of manufacturing a plurality of front wafers in an n-side up type in the method of manufacturing the vertically stacked microdisplay panel of the present invention;

FIGS. 13 and 14 illustrate a process of manufacturing a plurality of front wafers in a p-side up type in the method of manufacturing the vertically stacked microdisplay panel of the present invention; and

FIGS. 15 to 17 illustrate a process of manufacturing a vertically stacked microdisplay panel according to the method of manufacturing the vertically stacked microdisplay panel of the present invention.

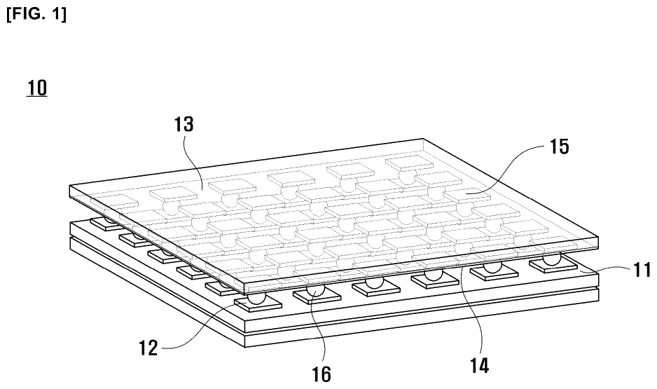

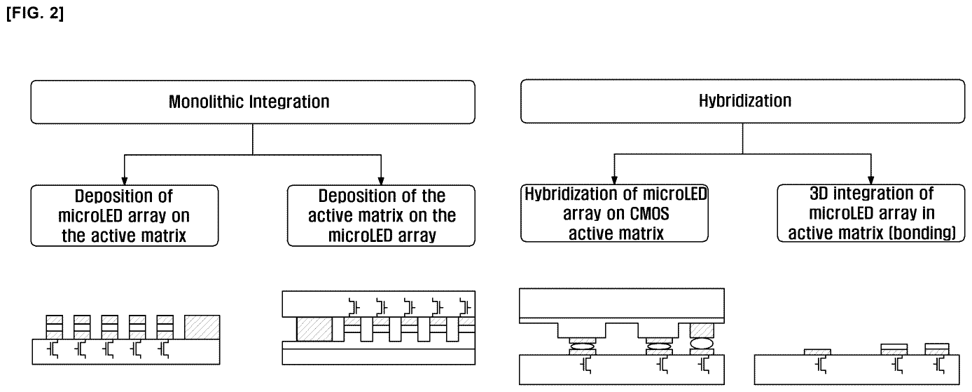

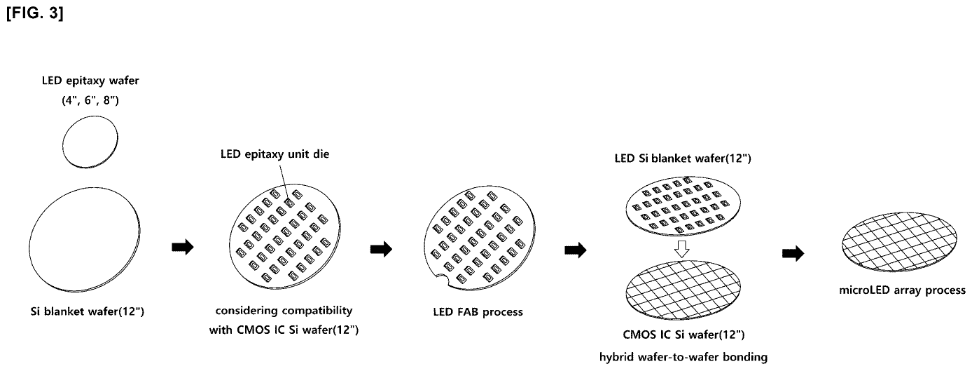

### DETAILED DESCRIPTION OF EXEMPLARY EMBODIMENTS

Hereinafter, some embodiments of the present invention will be described in detail with reference to exemplary drawings. When reference numerals are assigned to components of each drawing, it should be noted that, when the same components are illustrated in different drawings, the same numerals are assigned to the same components whenever possible.

Further, in description of embodiments of the present invention, detailed description of related well-known configurations or functions that is determined to interfere with the understanding of the embodiments of the present invention will be omitted.

Further, in describing components of the embodiments of the present invention, terminologies such as “first,” “second,” “A,” “B,” “(a),” and “(b)” may be used. These terms are used to distinguish a component from another component but a nature, an order, or a sequence of the elements is not limited by the terminology.

Hereinafter, a vertically stacked microdisplay panel 100 according to a first embodiment of the present invention will be described in detail with reference to the accompanying drawings.

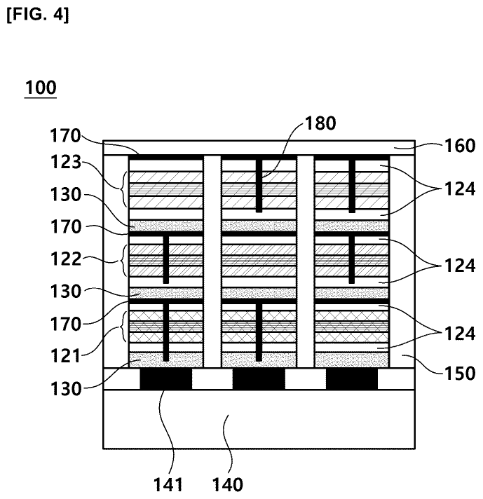

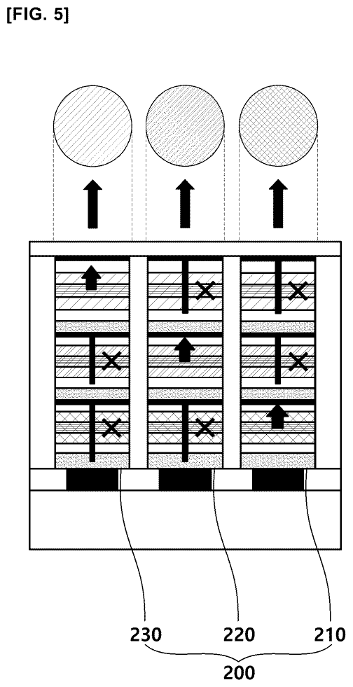

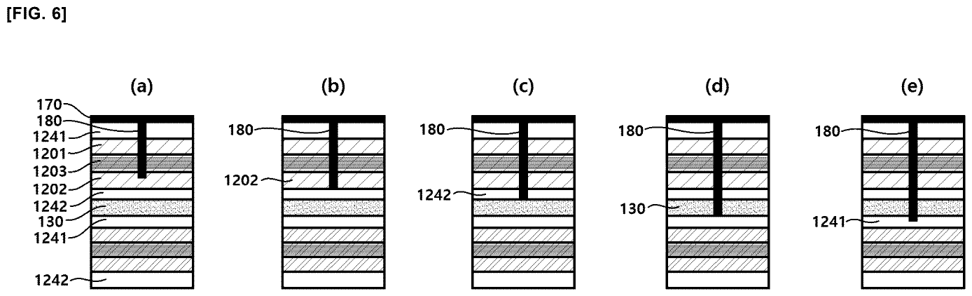

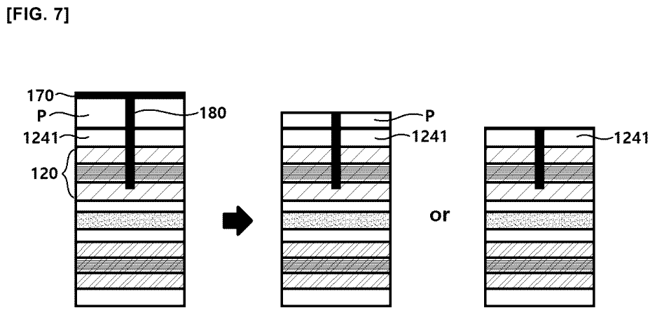

FIG. 4 is a diagram illustrating the entirety of a vertically stacked microdisplay panel according to the first embodiment of the present invention, FIG. 5 is a diagram illustrating a plurality of light-emitting diode (LED) stacks of the vertically stacked microdisplay panel according to the first embodiment of the present invention that each emit only a specific color, FIG. 6 illustrates diagrams of short paths of the vertically stacked microdisplay panel according to the first embodiment of the present invention that are formed to have different depths, and FIG. 7 is a diagram illustrating a transparent layer that is removed through a protective layer of the vertically stacked microdisplay panel according to the first embodiment of the present invention.

As illustrated in FIGS. 4 and 5, the vertically stacked microdisplay panel 100 according to the first embodiment of the present invention includes a back wafer 140, a plurality of LED stacks 200, a mold portion 150, and a common electrode 160.

The back wafer 140 is an active driving integrated circuit (IC) driven by an active matrix (AM) method and is a complementary metal-oxide-semiconductor (CMOS) wafer, on an upper surface of which a plurality of CMOS electrode pads 141 are arranged in an array. A passivation layer may be formed on the upper surface of the back wafer 140 so that upper surfaces of the plurality of CMOS electrode pads 141 are not exposed, and a portion of the passivation layer may be etched so that the plurality of CMOS electrode pads 141 are exposed when a front wafer is bonded.

Here, the back wafer 140 may be provided as a Si wafer having a (100) crystal plane, and may be provided as an 8-inch or 12-inch Si wafer according to a standard CMOS IC process. However, considering that the size of a typical LED wafer (front wafer) for bonding is 4 inches or 6 inches, the size of the back wafer 140 is not particularly limited.

The plurality of LED stacks 200 are each aligned on the plurality of CMOS electrode pads 141 and each include a plurality of light-emitting units 120 and a plurality of bonding layers 130 that are stacked in a vertical direction.

The light-emitting units 120 generate light and may emit blue light, green light, or red light. In the present invention, when the light-emitting units 120 emit blue light or green light, binary, ternary, or quaternary compounds such as InN, InGaN, GaN, AlGaN, AlN, AlGaInN, etc., which are group III (Al, Ga, In) nitride semiconductors among group III-V compound semiconductors, may be arranged at an appropriate position and order on an initial growth wafer G and epitaxially grown.

In particular, in order to emit blue light or green light, a high-quality group III nitride semiconductor such as InGaN with a high In composition should be preferentially formed on top of a group III nitride semiconductor composed of GaN, AlGaN, AlN, or AlGaInN, but the present invention is not limited thereto.

Further, in the present invention, when the light-emitting units 120 emit red light, binary, ternary, and quaternary compounds such as InP, InGaP, GaP, AlInP, AlGaP, AIP, AlGaInP, etc., which are group III (Al, Ga, In) phosphide semiconductors among group III-V compound semiconductors, may be arranged at an appropriate position and order on the initial growth wafer G and epitaxially grown. Further, according to recent trends, in order to develop equipment and process technology and further improve the value of display panel products, when red light is emitted, a high-quality group III nitride semiconductor such as InGaN with a high In composition of 30% or more may be preferentially formed on top of a group III nitride semiconductor composed of GaN, AlGaN, AlN, and AlGaInN, rather than a group III phosphide semiconductor.

In particular, in order to emit red light, a high-quality group III phosphide semiconductor such as InGaP with a high In composition should be preferentially formed on top of a group III phosphide semiconductor composed of GaP, AlInP, AlGaP, AIP, and AlGaInP, but the present invention is not limited thereto, and hereinafter, for convenience of description, the following description will be given on the basis of a group III nitride semiconductor.

Each light-emitting unit 120 includes, more specifically, a first semiconductor region 1201 (e.g., p-type or n-type), an active region 1203 (e.g., multi quantum wells (MQWs)), and a second semiconductor region 1202 (e.g., n-type when the first semiconductor region 1201 is p-type or p-type when the first semiconductor region is n-type), and may have a structure in which the second semiconductor region 1202, the active region 1203, and the first semiconductor region 1201 are epitaxially grown on the initial growth wafer G, and ultimately have an overall thickness of about 5.0 to 8.0 μm including multiple layers of a group III nitride, but the present invention is not limited thereto. Hereinafter, the following description will be given on the basis of the case in which the first semiconductor region 1201 is p-type and the second semiconductor region 1202 is n-type.

The second semiconductor region 1202 has a second conductivity (e.g., n-type) and is formed on the growth wafer G. The second semiconductor region 1202 may have a thickness of 2.0 to 3.5 μm and has a surface with nitrogen polarity (N-polarity).

The active region 1203 generates light by utilizing the recombination of electrons and holes and is formed on the second semiconductor region 1202. The active region 1203 may have a thickness of several tens of nm in multiple layers.

The first semiconductor region 1201 has a first conductivity (e.g., p-type) and is formed on the active region 1203. The first semiconductor region 1201 may have a thickness of several tens of nm in multiple layers and has an upper surface with gallium polarity (Ga-polarity).

That is, the active region 1203 is interposed between the first semiconductor region 1201 and the second semiconductor region 1202 so that when holes in the first semiconductor region 1201, which is a p-type semiconductor region, and electrons in the second semiconductor region 1202, which is an n-type semiconductor region, recombine in the active region 1203, light is generated.

The plurality of LED stacks 200 include a first LED stack 210 for emitting only a first color, a second LED stack 220 for emitting only a second color, and a third LED stack 230 for emitting only a third color.

Further, each of the first LED stack 210, the second LED stack 220, and the third LED stack 230 may have a tandem structure in which the plurality of light-emitting units 120 and the bonding layer 130 are stacked in the vertical direction, and may include, more specifically, a first light-emitting unit 121 that is bonded onto the CMOS electrode pad 141 through a first bonding layer 131 to emit the first color, a second light-emitting unit 122 that is bonded onto the first light-emitting unit 121 through a second bonding layer 132 to emit the second color, and a third light-emitting unit 123 that is bonded onto the second light-emitting unit 122 through a third bonding layer 133 to emit the third color.

In this case, in the present invention, in consideration of a wavelength of light, it is preferable that the first color of the first light-emitting unit 121 of a lower layer be red with a long wavelength, the second color of the second light-emitting unit 122 of a middle layer be green, and the third color of the third light-emitting unit 123 of an upper layer be blue with a short wavelength, but the present invention is not limited thereto.

In the present invention, each of the first light-emitting unit 121, the second light-emitting unit 122, and the third light-emitting unit 123 may be stacked in an n-side up type or a p-side up type. Further, an ohmic contact electrode 124 that is electrically connected to the light-emitting unit 120 through ohmic contact may be formed on at least one of upper and lower surfaces of each of the first light-emitting unit 121, the second light-emitting unit 122, and the third light-emitting unit 123, and specifically, a first ohmic contact electrode 1241 may be formed in contact with the first semiconductor region 1201, and a second ohmic contact electrode 1242 may be formed in contact with the second semiconductor region 1202.

The ohmic contact electrode 124 may be formed of a material having transparent conductivity. The material of the first ohmic contact electrode 1241 formed in contact with the first semiconductor region 1201, which is a p-type semiconductor, may include NiO, PtO, PdO, AgO2, Au, Rh2O3, RuO2, In2O3, SnO2, ZnO, IZO, ITO, and/or IGZO, and the material of the second ohmic contact electrode 1242 formed in contact with the second semiconductor region 1202, which is an n-type semiconductor, may include TiN, CrN, VN, In2O3, SnO2, ZnO, IZO, ITO, and/or IGZO. Furthermore, since the surface of the second semiconductor region 1202 having nitrogen polarity (N-polarity) has a much higher surface roughness than the surface of the first semiconductor region 1201 having gallium polarity (Ga-polarity), it is preferable to introduce a chemical-mechanical polishing (CMP) process for polishing and planarizing the surface of the second semiconductor region 1202, prior to forming the ohmic contact electrode 124 having transparent conductivity.

Further, the surface of the ohmic contact electrode 124 may also be polished and smoothly planarized through mechanical polishing (MP) or CMP.

Further, the bonding layer 130 (including the first bonding layer 131, the second bonding layer 132, and the third bonding layer 133) is formed of a ceramic material that is optically transparent and electrically conductive, i.e., transparently conductive, and here, “optically transparent” means transparent (transmittance of 80% or more) or translucent (semitransparent with transmittance of 50% or more) in a wavelength band of light (including visible light) used in an optical exposure (photolithography) process, and “electrically conductive” means having an electrical resistance of less than 10-3 Ω/cm. Such a ceramic material having transparency and conductivity may include a transparent conductive oxide (TCO), a transparent conductive nitride (TCN), and/or a transparent conductive oxide nitride (TCON).

In this case, when the ceramic material is a TCO, the ceramic material may include In2O3, SnO2, ZnO, IZO, ITO, and IGZO, when the ceramic material is a TCN, the ceramic material may include TiN, CrN, and VN, and when the ceramic material is a TCON, the ceramic material may include InON, SnON, ZnON, IZON, ITON, and IGZON.

In the present invention, each of the plurality of LED stacks 200 has a short path 180 formed in at least one of the plurality of light-emitting units 120 so that a current may flow through the light-emitting unit 120 in which the short path 180 is not formed, thereby emitting only a specific color without a color filter. In other words, each of the plurality of LED stacks 200 of the present invention may emit only a specific color by bypassing a current to the light-emitting unit 120, in which the short path 180 is not formed, so that a current does not flow to the light-emitting unit 120 in which the short path 180 is formed.

More specifically, among the plurality of LED stacks 200, the first LED stack 210 of the present invention has a short path 180 formed in each of the third light-emitting unit 123 and the second light-emitting unit 122, and thus a current may flow only through the first light-emitting unit 121 and only the first color may be emitted. In this case, an upper side of the short path 180 may be electrically connected to the common electrode 160 through a transparent layer 170 which will be described below.

Further, the second LED stack 220 has a short path 180 formed in each of the third light-emitting unit 123 and the first light-emitting unit 121, a current may flow only through the second light-emitting unit 122, and only the second color may be emitted. In this case, an upper side of the short path 180 may be electrically connected to the third bonding layer 133 through a transparent layer 170 which will be described below.

Further, the third LED stack 230 has a short path 180 formed in each of the second light-emitting unit 122 and the first light-emitting unit 121, a current may flow only through the third light-emitting unit 123, and only the third color may be emitted. In this case, an upper side of the short path 180 may be electrically connected to the second bonding layer 132 through a transparent layer 170 which will be described below.

Meanwhile, in the present invention, in order to form the short path 180, a through-hole may be formed and then the through-hole may be filled with an optically transparent and electrically conductive material, and after the through-hole is filled therewith, the corresponding material may remain on the surface of the light-emitting unit 120 or be removed, and in this case, when the corresponding material remains on the light-emitting unit 120, the transparent layer 170 may be formed.

Here, forming the short path 180 after forming the through-hole may mean that the short path 180 may be formed by filling the corresponding through-hole in a direct self-align manner or by filling the corresponding through-hole in a liquid coating manner, but the present invention is not limited thereto, and any method may be used to form the short path 180 in the through-hole.

Specifically, the short path 180 may be formed in the first light-emitting unit 121 and then the transparent layer 170 electrically connected to the corresponding short path 180 may be formed, the short path 180 may be formed in the second light-emitting unit 122, and then the transparent layer 170 electrically connected to the corresponding short path 180 may be formed, the short path 180 may be formed in the third light-emitting unit 123, and then the transparent layer 170 electrically connected to the corresponding short path 180 may be formed. In this case, all the short paths 180 and the transparent layers 170 may be formed of an optically transparent and electrically conductive material.

Meanwhile, in the present invention, the through-hole may be filled with a non-transparent conductive material to form the short path 180, and in this case, the corresponding material should be removed so as not to remain on the surface of the bonding layer 130 on the light-emitting unit 120 after the through-hole is filled, and the transparent layer 170 may be formed of a separate material that is optically transparent and electrically conductive.

The short path 180 may be formed of an optically transparent and electrically conductive material or a metallic material having non-transparent properties. When the short path 180 is formed of an optically transparent and electrically conductive material, it is preferable to form the short path 180 of a material having low resistance and high transmittance characteristics. Such materials may include In2O3, SnO2, ZnO, IZO, ITO, IGZO, etc., but the present invention is not limited thereto. Further, when the short path 180 is formed of a metallic material, such materials may include Ag, Cu, Au, Pd, Pt, Ni, Mo, W, and electrically conducting nano-particles, but the present invention is not limited thereto.

Further, the transparent layer 170 may also be formed of an optically transparent and electrically conductive material, and it is preferable to form the transparent layer 170 of a material having the same low resistance and high transmittance characteristics. Such materials may include In2O3, SnO2, ZnO, IZO, ITO, IGZO, etc., but the present invention is not limited thereto.

In the present invention, the plurality of LED stacks 200 arranged and aligned on the plurality of CMOS electrode pads 141 are separated in preset units, and here, a preset unit is a pixel or sub-pixel unit and may be a diameter (width) of the plurality of LED stacks 200.

Further, as illustrated in FIG. 5, in the present invention, light-emitting areas of the plurality of LED stacks 200 may all be the same, and operating voltages of the plurality of LED stacks 200 may all be set to be the same. Specifically, the present invention has a stacked structure, but the series connections are all disconnected by flowing the current through the short paths 180. That is, in the present invention, since this is the same as a parallel structure, the operating voltages may all be set to be the same (e.g., 3 V).

Meanwhile, as illustrated in FIG. 6, in the present invention, the short path 180 may have a preset width (diameter), and specifically, in the present embodiment, the width of the short path 180 may be smaller than a width of the light-emitting unit 120 (i.e., less than 100% of a pixel width or a width of the light-emitting unit 120) so as to pass through the light-emitting unit 120. The width of the short path 180 of the present invention increases in an area ratio as a chip size decreases, and the short path 180 of the present invention may be applied not only to micro LEDs but also to mini LEDs or normal LEDs.

Further, as illustrated in FIG. 6, the short path 180 of the present invention may have a preset depth for electrical shorting.

Specifically, as illustrated in FIG. 6A, a short path 180 may be formed to extend from at least the first ohmic contact electrode 1241 to pass through the first semiconductor region 1201 and the active region 1203 and then pass through a portion of the second semiconductor region 1202 at a lower side, as illustrated in FIG. 6B, a short path 180 may be formed to extend from at least the first ohmic contact electrode 1241 to pass through the first semiconductor region 1201 and the active region 1203 and then pass through an entire portion of the second semiconductor region 1202 at the lower side, as illustrated in FIG. 6C, a short path 180 may be formed to extend from at least the first ohmic contact electrode 1241 to pass through the first semiconductor region 1201, the active region 1203, and the second semiconductor region 1202 and then pass through an entire portion of the second ohmic contact electrode 1242 at the lower side, as illustrated in FIG. 6D, a short path 180 may be formed to extend from at least the first ohmic contact electrode 1241 to pass through the first semiconductor region 1201, the active region 1203, the second semiconductor region 1202, and the second ohmic contact electrode 1242 and then pass through an entire portion of the bonding layer 130 at the lower side, or as illustrated in FIG. 6E, a short path 180 may be formed to extend from at least the first ohmic contact electrode 1241 at an upper side to pass through the first semiconductor region 1201, the active region 1203, the second semiconductor region 1202, the second ohmic contact electrode 1242, and the bonding layer 130 and then pass through a portion of the first ohmic contact electrode 1241 at the lower side.

Furthermore, when the light-emitting unit 120 is a p-side up type, a short path 180 may be formed to extend from at least the first ohmic contact electrode 1241 of a p-type through the first semiconductor region 1201 and the active region 1203 and then pass through a portion of the second semiconductor region 1202 at a lower side. Further, when the light-emitting unit 120 is an n-side up type, a short path 180 may be formed to extend from at least the second ohmic contact electrode 1242 of an n-type to pass through the second semiconductor region 1202 and the active region 1203 and then pass through an entire portion of the first semiconductor region 1201 at a lower side. However, depths of the short paths 180 are not limited to the above-described examples and various depths are possible as necessary.

Meanwhile, as illustrated in FIG. 7, when it is necessary to remove the transparent layer 170 formed on the first ohmic contact electrode 1241, a protective layer P may be formed on the first ohmic contact electrode 1241, and formed on each first ohmic contact electrode 1241 on the light-emitting unit 120 of each layer. The protective layer P may remain after the transparent layer 170 is removed or may be removed together with the transparent layer 170, and when the protective layer P remains, the short path 180 may be formed to pass through the protective layer P and the first ohmic contact electrode 1241.

The mold portion 150 supports a vertically stacked light-emitting diode on silicon (LEDoS) structure and is formed to fill a space between the plurality of aligned LED stacks 200.

The common electrode 160 may be formed on the plurality of LED stacks 200 in which the mold portion 150 is formed, the common electrode 160 may be formed of a material having transparent conductivity similar to the ohmic contact electrode 124, when the common electrode 160 is a positive electrode, the material of the common electrode 160 may include NiO, PtO, PdO, AgO2, Au, Rh2O3, RuO2, In2O3, SnO2, ZnO, IZO, ITO, and IGZO, and when the common electrode 160 is a negative electrode, the material of the common electrode 160 may include TiN, CrN, VN, In2O3, SnO2, ZnO, IZO, ITO, and IGZO.

Further, a surface of the common electrode 160 may also be polished and smoothly planarized through MP or CMP.

Furthermore, although not illustrated, a coating layer made of a transparent organic material may be additionally formed to protect the common electrode 160 from the atmospheric environment.

Hereinafter, a vertically stacked microdisplay panel 200 according to a second embodiment of the present invention will be described in detail with reference to the accompanying drawings.

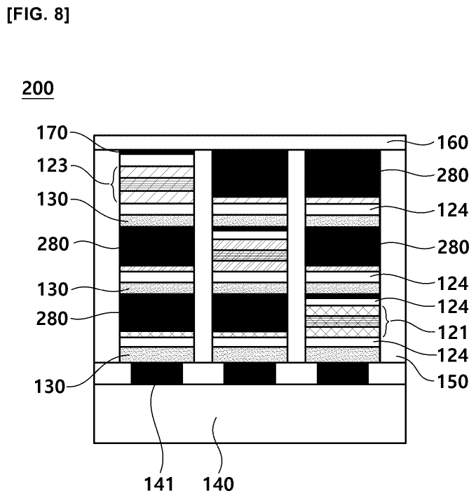

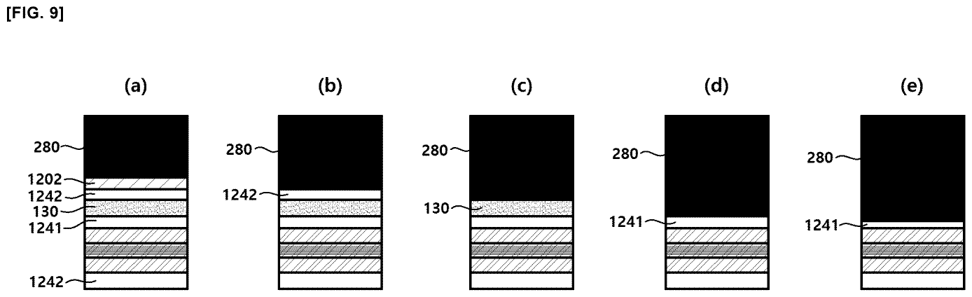

FIG. 8 is a diagram illustrating the entirety of a vertically stacked microdisplay panel according to the second embodiment of the present invention, and FIG. 9 illustrates diagrams of short paths of the vertically stacked microdisplay panel according to the second embodiment of the present invention that are formed to have different depths.

As illustrated in FIG. 8, the vertically stacked microdisplay panel 200 according to the second embodiment of the present invention includes a back wafer 140, a plurality of LED stacks 200, a mold portion 150, and a common electrode 160.

Here, since the details of the back wafer 140, the plurality of LED stacks 200, the mold portion 150, and the common electrode 160 that are not described are the same as those of the vertically stacked microdisplay panel 100 according to the first embodiment of the present invention described above, redundant descriptions will be omitted.

Meanwhile, as illustrated in FIG. 9, in the present invention, a short path 280 may have a preset width (diameter), and specifically, in the present embodiment, a width of the short path 280 may correspond to a width of a light-emitting unit 120 (i.e., a pixel width or 100% of a width of the light-emitting unit 120).

Further, as illustrated in FIG. 9, the short path 280 of the present invention may have a preset depth for electrical shorting.

Specifically, as illustrated in FIG. 9A, a short path 280 may be formed to extend from at least a first ohmic contact electrode 1241 through a first semiconductor region 1201 and an active region 1203 to a portion of a second semiconductor region 1202 at a lower side, as illustrated in FIG. 9B, a short path 280 may be formed to extend from at least the first ohmic contact electrode 1241 through the first semiconductor region 1201 and the active region 1203 to an entire portion of the second semiconductor region 1202 at the lower side, as illustrated in FIG. 9C, a short path 280 may be formed to extend from at least a portion of the first ohmic contact electrode 1241 through the first semiconductor region 1201, the active region 1203, and the second semiconductor region 1202 to an entire portion of a second ohmic contact electrode 1242 at the lower side, as illustrated in FIG. 9D, a short path 280 may be formed to extend from at least a portion of the first ohmic contact electrode 1241 through the first semiconductor region 1201, the active region 1203, the second semiconductor region 1202, and the second ohmic contact electrode 1242 to an entire portion of the bonding layer 130 at the lower side, or as illustrated in FIG. 9E, a short path 280 may be formed to extend from at least the first ohmic contact electrode 1241 at an upper side through the first semiconductor region 1201, the active region 1203, the second semiconductor region 1202, the second ohmic contact electrode 1242, and a bonding layer 130 to a portion of the first ohmic contact electrode 1241 at the lower side.

Furthermore, when the light-emitting unit 120 is a p-side up type, a short path 280 may be formed to extend from at least a portion of the first ohmic contact electrode 1241 of a p-type through the first semiconductor region 1201 and the active region 1203 to a portion of the second semiconductor region 1202 at the lower side. Further, when the light-emitting unit 120 is in an n-side up type, the short path 280 may be formed to extend from at least the second ohmic contact electrode 1242 of an n-type through the second semiconductor region 1202 and the active region 1203 to an entire portion of the first semiconductor region 1201 at the lower side. However, depths of the short paths 280 are not limited to the above-described examples and various depths are possible as necessary.

Meanwhile, in the present invention, in order to form the short path 280, an entire portion of a corresponding region of the LED stack 200 rather than a through-hole is etched and then filled with an optically transparent and electrically conductive material to form the short path 280, and in this case, the entire short path 280 serves as a transparent layer. That is, the short path 280 of the present invention is preferably formed of an optically transparent and electrically conductive material, and in particular, is preferably formed of a material having low resistance and high transmittance characteristics. Such materials may include In2O3, SnO2, ZnO, IZO, ITO, IGZO, etc., but the present invention is not limited thereto.

Hereinafter, a method of manufacturing a vertically stacked microdisplay panel of the present invention (S100) will be described in detail with reference to the accompanying drawings.

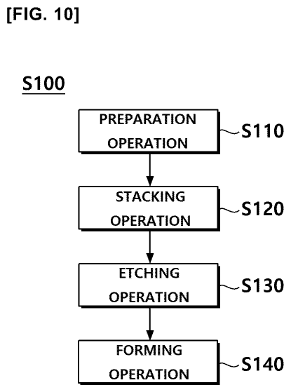

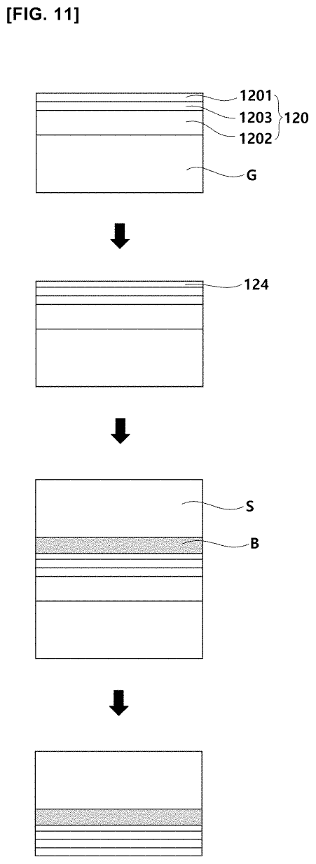

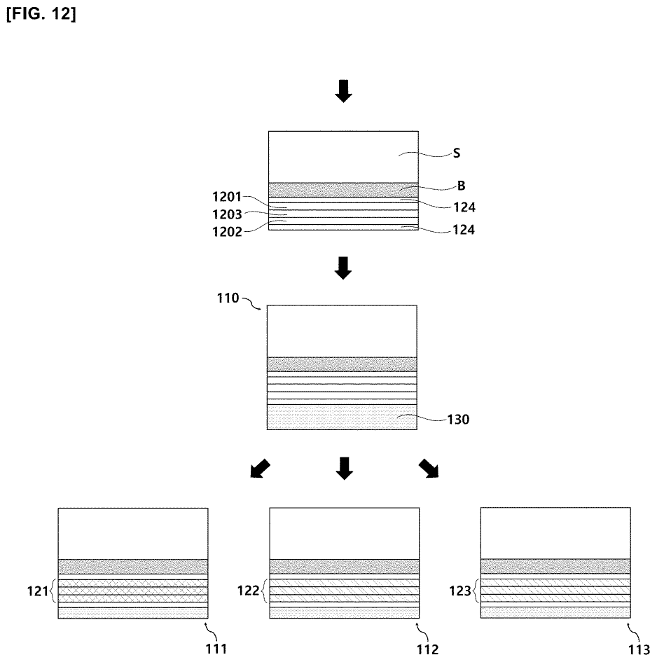

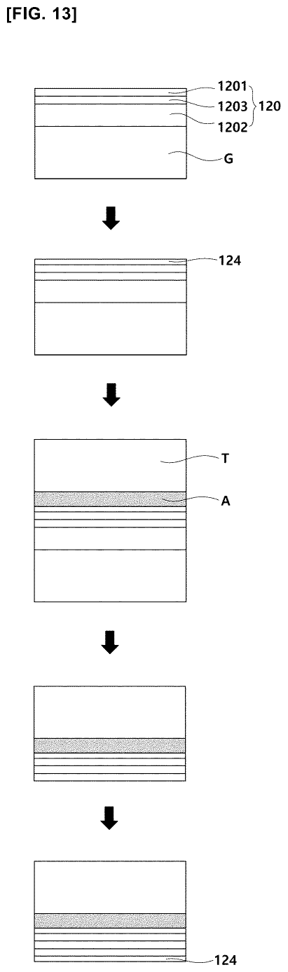

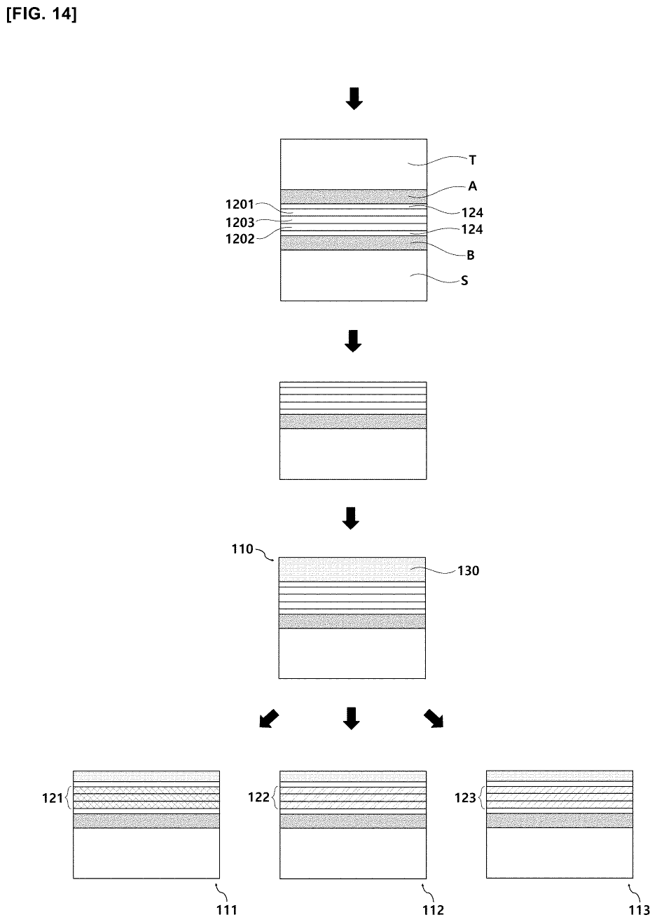

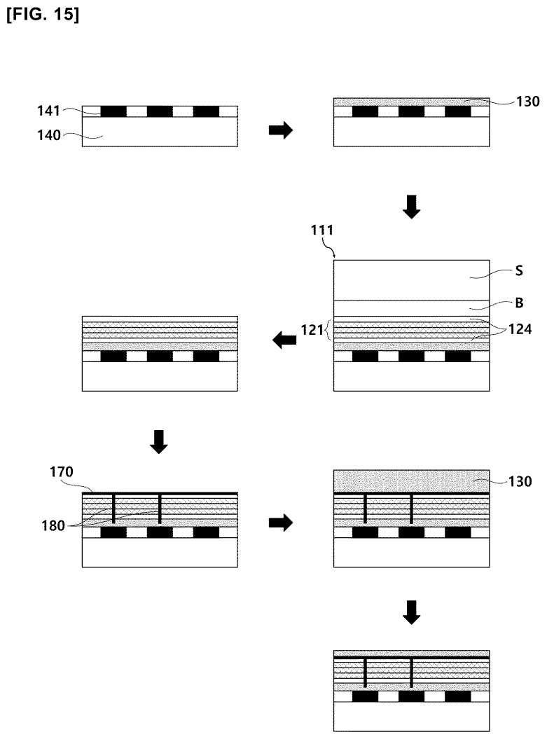

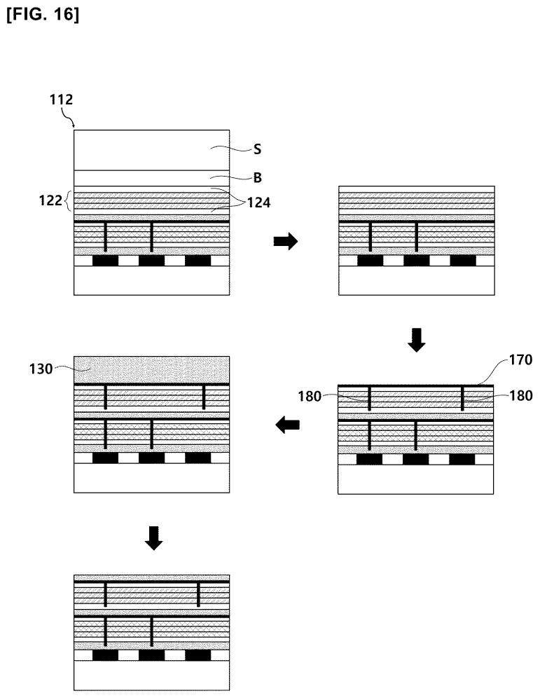

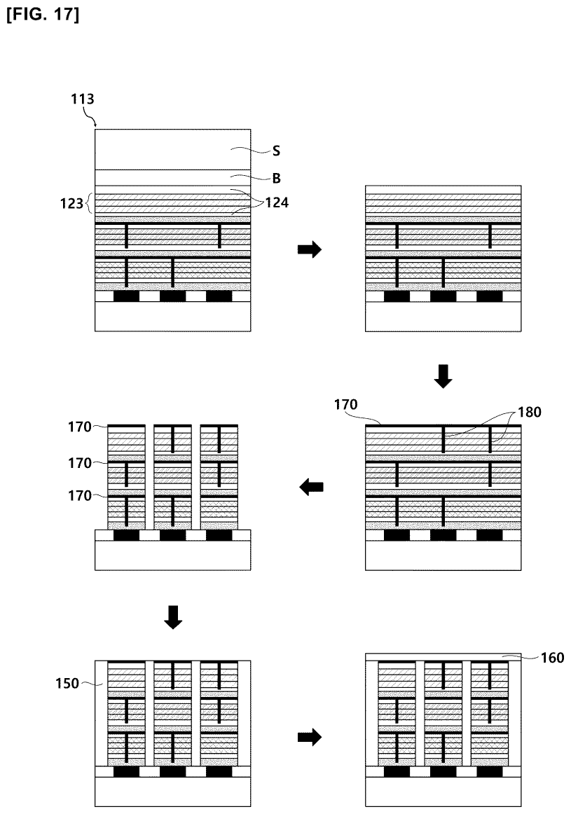

FIG. 10 is a flowchart of a method of manufacturing the vertically stacked microdisplay panel of the present invention, FIGS. 11 and 12 illustrate a process of manufacturing a plurality of front wafers in an n-side up type in the method of manufacturing the vertically stacked microdisplay panel of the present invention, FIGS. 13 and 14 illustrate a process of manufacturing a plurality of front wafers in a p-side up type in the method of manufacturing the vertically stacked microdisplay panel of the present invention, and FIGS. 15 to 17 illustrate a process of manufacturing a vertically stacked microdisplay panel according to the method of manufacturing the vertically stacked microdisplay panel of the present invention.

As illustrated in FIG. 10, the method of manufacturing the vertically stacked microdisplay panel of the present invention (S100) includes a preparation operation S110, a stacking operation S120, an etching operation S130, and a forming operation S140.

The preparation operation S110 is an operation of preparing a plurality of front wafers 110 and preparing a back wafer 140.

The plurality of front wafers 110 are each intended to emit different colors, and the plurality of front wafers 110 may include a first front wafer 111 for emitting a first color, a second front wafer 112 for emitting a second color different from the first color, and a third front wafer 113 for emitting a third color different from the first color and the second color. Meanwhile, the first color, the second color, and the third color may be, for example, red, green, and blue, respectively, but the present invention is not limited thereto, and various other colors may be included.

Here, the plurality of front wafers 110 include, more specifically, the first front wafer 111 including a support wafer S and a first light-emitting unit 121 disposed on top of the support wafer S, the second front wafer 112 including a support wafer S and a second light-emitting unit 122 disposed on top of the support wafer S, and a third front wafer 113 including a support wafer S and a third light-emitting unit 123 disposed on top of the support wafer S.

In the present invention, materials of a growth wafer G, a temporary wafer T, and/or the support wafer S may each be either silicon (Si) or sapphire, but the selection of the material may be determined according to a wafer bonding method.

Meanwhile, the front wafers 110 of the present invention may be manufactured in an n-side up type in which a second semiconductor region 1202 having a second conductivity (n-type) is exposed to the outside as illustrated in FIGS. 11 and 12, or may be manufactured in a p-side up type in which a first semiconductor region 1201 having a first conductivity (p-type) is exposed to the outside as illustrated in FIGS. 13 and 14.

Accordingly, when the front wafer 110 is an n-side up type, the front wafer 110 has a structure in which a Si support wafer S having a (111), (110), or the (100) crystal plane, a bonding layer B, an ohmic contact electrode 124, a first semiconductor region 1201, an active region 1203, a second semiconductor region 1202, an ohmic contact electrode 124, and a bonding layer 130 are sequentially stacked, and the Si support wafer S has no difference in thermal expansion coefficient when subsequently bonded to the Si back wafer 140, and thus contributes to the stabilization of the quality of the vertically stacked microdisplay panel.

Further, when the front wafer 110 is a p-side up type, the front wafer 110 has a structure in which a Si support wafer S having a (111), (110), or the (100) crystal plane, a bonding layer B, an ohmic contact electrode 124, a second semiconductor region 1202, an active region 1203, a first semiconductor region 1201, an ohmic contact electrode 124, and a bonding layer 130 are sequentially stacked, and the Si support wafer S has no difference in thermal expansion coefficient when subsequently bonded to the Si back wafer 140, and thus contributes to the stabilization of the quality of the vertically stacked microdisplay panel.

Meanwhile, in the case of manufacturing a p-side up type, instead of using bonding two times through the temporary wafer T as illustrated in FIGS. 13 and 14, the light-emitting unit 120 may be grown on the initial growth wafer G and then the ohmic contact electrode 124 may be formed to manufacture the front wafer 110 in a p-side up type.

The stacking operation S120 is an operation of stacking a plurality of light-emitting units 120 and a bonding layer 130 on the Si back wafer 140 in a vertical direction by repeatedly bonding the front wafer 110 with its top and bottom reversed on the Si back wafer 140 through the bonding layer 130 so that the light-emitting units 120 of the front wafer 110 face CMOS electrode pads 141 of the Si back wafer 140, that is, so that the light-emitting units 120 of the front wafer 110 and the CMOS electrode pads 141 of the Si back wafer 140 face each other, and then removing the support wafer S.

In this case, in the stacking operation S120, after the support wafer S of the front wafer 110 and the bonding layer 130 are removed, a short path may be formed in a specific portion of the light-emitting unit. In this case, the short path may have a preset depth and width.

The etching operation S130 is an operation in which the plurality of LED stacks 200 are arranged on the plurality of CMOS electrode pads 141 by etching the plurality of stacked light-emitting units 120 and the bonding layer 130 and separating in preset units, and is an operation that eliminates the need for a process of aligning LED stacks 200 of a conventional front wafer 110 and CMOS electrode pads 141 of a back wafer 140.

After the etching operation S130 described above is performed, among the plurality of LED stacks 200, a first LED stack 210 of the present invention has a short path 180 formed in each of a third light-emitting unit 123 and a second light-emitting unit 122 so that a current may flow only through a first light-emitting unit 121 and only a first color may be emitted. Further, a second LED stack 220 has a short path 180 formed in each of the third light-emitting unit 123 and the first light-emitting unit 121 so that a current may flow only through the second light-emitting unit 122 and only a second color may be emitted. Further, a third LED stack 230 has a short path 180 formed in each of the second light-emitting unit 122 and the first light-emitting unit 121 so that a current may flow only through the third light-emitting unit 123 and only a third color may be emitted.

The forming operation S140 is an operation of forming a mold portion 150 that fills a space between the plurality of aligned LED stacks 200 and then forming a common electrode 160 on the plurality of LED stacks 200.

According to the present invention, since a color filter is unnecessary despite the adoption of a vertically stacked tandem structure, the color quality of a microdisplay can be significantly improved, and process complexity and productivity can be significantly improved.

Further, according to the present invention, unlike the existing monolithic integration method or hybrid method that has alignment issues, an engineering monolithic epitaxy wafer is first manufactured, and then stacks on the engineering monolithic epitaxy wafer are etched and separated in preset units so that a plurality of LED stacks are aligned on a plurality of CMOS electrode pads, and thus not only small-diameter wafers of 6 inches or less but also large-diameter wafers of 8 inches or more can be used, which has the effect of significantly increasing the product yield.

Further, according to the present invention, since a bonding layer and an ohmic contact electrode are made of an electrically conductive transparent ceramic material rather than a metal, the possibility of an electrical short failure can be significantly reduced, and the element reliability can be significantly improved. Further, a plasma dry process for LED stack alignment has the effect of facilitating etching while preventing the problem of re-deposition of etching by-products. Moreover, the ease of etching described above provides a much better advantage in the production of high-resolution microdisplays having ultra-fine pixels of less than 3 μm.

Further, according to the present invention, since a light-emitting unit, a bonding layer, and an ohmic contact electrode are all transparent and allow visible light to pass through, there is an effect of eliminating alignment error issues in an exposure process.

Meanwhile, effects of the present invention are not limited to the above-described effects and it is clear to those skilled in the art that various effects may be included from the above detailed descriptions.

While the above-described embodiments of the present invention describe that all components are combined into one unit or are operated in a combined manner, the present invention is not limited thereto. That is, within the scope of the present invention, at least one of the components may be selectively combined and operated

In addition, the terms “include,” “comprise,” “have,” etc., as described above, unless otherwise specifically stated, imply that a corresponding component may be present, and therefore it should be understood that another component may be further included rather than being excluded unless otherwise stated. Unless otherwise defined, all terms including technical and scientific terms used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In addition, the above description is only an example describing the technical spirit of the present invention, and it will be understood by those of skilled in the art that various changes and modifications in form and details may be made without departing from the spirit and scope of the present invention.

Therefore, the embodiments disclosed in the present invention should be considered in a descriptive sense only and not for limiting the technological scope. The technical spirit of the present invention is not limited by these embodiments. It should be understood that the scope of the present invention is defined by the appended claims and encompasses all equivalents that fall within the scope of the appended claims.

What is claimed is:

1. A vertically stacked microdisplay panel comprising:
a back wafer having an upper surface on which a plurality of complementary metal-oxide-semiconductor (CMOS) electrode pads are arranged;
a plurality of light-emitting diode (LED) stacks, each of which includes a plurality of light-emitting units and a plurality of bonding layers that are stacked in a vertical direction and is arranged on one of a plurality of CMOS electrode pads; and
a common electrode formed on the plurality of LED stacks,
wherein each of the plurality of LED stacks, by forming a short path in at least one of the plurality of light-emitting units, allows a current to flow through the light-emitting unit in which the short path is not formed, and emits only a specific color, and
the short path has a preset depth and a preset width.

2. The vertically stacked microdisplay panel of claim 1, wherein the plurality of LED stacks include a first LED stack for emitting only a first color, a second LED stack for emitting only a second color, and a third LED stack for emitting only a third color, and
the first LED stack, the second LED stack and the third LED stack are formed so that a first light-emitting unit is disposed on the CMOS electrode pad and emits the first color, a second light-emitting unit is disposed on the first light-emitting unit and emits the second color, and a third light-emitting unit is disposed on the second light-emitting unit and emits the third color.

3. The vertically stacked microdisplay panel of claim 2, wherein the first LED stack, by forming the short path in each of the third light-emitting unit and the second light-emitting unit, allows a current to flow only through the first light-emitting unit and emits only the first color,
the second LED stack, by forming the short path in each of the first light-emitting unit and the third light-emitting unit, allows a current to flow only through the second light-emitting unit and emits only the second color, and
the third LED stack, by forming the short path in each of the first light-emitting unit and the second light-emitting unit, allows a current to flow only through the third light-emitting unit and emits only the third color.

4. The vertically stacked microdisplay panel of claim 1, wherein the light-emitting unit includes a first semiconductor region having a first conductivity, an active region, and a second semiconductor region having a second conductivity,
a first ohmic contact electrode is formed in contact with the first semiconductor region, and
a second ohmic contact electrode is formed in contact with the second semiconductor region.

5. The vertically stacked microdisplay panel of claim 4, wherein the width of the short path is smaller than a width of the light-emitting unit.

6. The vertically stacked microdisplay panel of claim 5, wherein a protective layer is formed on the first ohmic contact electrode, and
the short path is formed to pass through the protective layer and the first ohmic contact electrode.

7. The vertically stacked microdisplay panel of claim 4, wherein the width of the short path corresponds to a width of the light-emitting unit.

8. The vertically stacked microdisplay panel of claim 4, wherein the short path is formed to extend from at least the first ohmic contact electrode to a portion of the second semiconductor region at a lower side.

9. The vertically stacked microdisplay panel of claim 4, wherein the short path is formed to extend from at least the first ohmic contact electrode to the second semiconductor region at a lower side.

10. The vertically stacked microdisplay panel of claim 4, wherein the short path is formed to extend from at least the first ohmic contact electrode to the second ohmic contact electrode at a lower side.

11. The vertically stacked microdisplay panel of claim 4, wherein the short path is formed to extend from at least the first ohmic contact electrode to the bonding layer at a lower side.

12. The vertically stacked microdisplay panel of claim 4, wherein the short path is formed to extend from at least the first ohmic contact electrode at an upper
side to a portion of the first ohmic contact electrode at a lower side.
